(19) United States
(12) Patent Application Publication
(10) Pub. No.: US 2007/0085081 A1
(43) Pub. Date: Apr. 19, 2007

(54) Thermally efficient semiconductor laser structure and method of forming same

(75) Inventor: Fow-Sen Choa, Ellicott City, MD (US)

Correspondence Address: FLESHNER & KIM, LLP, P.O. BOX 221200, CHANTILLY, VA, 20153, US

(73) Assignee: University of Maryland, Baltimore County

(21) Appl. No.: 11/252,724

(22) Filed: Oct. 19, 2005

(51) Int. Cl. H01L 33/00

(52) U.S. Cl. 257/79

(57) ABSTRACT

The present invention provides a thin-film semiconductor laser device that utilizes a double-sided heat removal technique and architecture. The term “thin-film semiconductor laser”, as used herein, refers to a semiconductor laser having a p-i-n structure, in which the thickness of the p-layer is no more than 10 times the thickness of the n-layer, or the thickness of the n-layer is no more than 10 times the thickness of the p-layer. The thin-film semiconductor laser device of the present invention exhibits a p-n junction temperature that is only a few degrees higher than the sub-mount temperature. This greatly reduces the thermally related losses and thermally generated stresses of the chip.

### BACKGROUND OF THE INVENTION

1. Field of the Invention

This invention relates semiconductor lasers and, more specifically, to a semiconductor laser structure that exhibits efficient heat dissipation.

2. Background of the Related Art

The primary losses in high power semiconductor lasers are those losses caused by increasing temperature, which include carrier loss due to the increasing number of thermal-ionic overflow carriers, carrier loss due to increased Auger recombination, and photon loss due to the inter-valence band absorptions occurring at high operating temperatures. These losses present themselves result in decreased quantum efficiency, reduced optical gain, and increased threshold current.

These losses raise the operating temperature, which in turn further increases the losses. A point is reached where increasing the bias current becomes counter-productive and the increasing high temperature losses result in reduced laser gain. The increased heat and reduced gain will then shut down the laser or catastrophically kill the laser through certain thermally induced problems.

### SUMMARY OF THE INVENTION

An object of the invention is to solve at least the above problems and/or disadvantages and to provide at least the advantages described hereinafter.

Therefore, an object of the present invention is to provide a thin-film semiconductor laser device with efficient heat dissipation.

Another object of the present invention is to provide a thin-film semiconductor laser device with a double-sided heat removing architecture.

To achieve the at least above objects, in whole or in part, there is provided a semiconductor laser device, including a thin-film semiconductor laser, a thermally conductive supporting layer attached to a first side of the thin-film semiconductor laser and a thermally conductive structure in thermal communication with a second side of the thin-film semiconductor laser.

Additional advantages, objects, and features of the invention will be set forth in part in the description which follows and in part will become apparent to those having ordinary skill in the art upon examination of the following or may be learned from practice of the invention. The objects and advantages of the invention may be realized and attained as particularly pointed out in the appended claims.

### BRIEF DESCRIPTION OF THE DRAWINGS

The invention will be described in detail with reference to the following drawings, in which like reference numerals refer to like elements, wherein:

FIG. 1 is a schematic diagram of one preferred thin film semiconductor laser structure 100 used in the thin film semiconductor laser device of the present invention;

FIG. 2 is a schematic diagram showing one preferred embodiment of the thin film semiconductor laser device of the present invention;

FIG. 3A is a FEMLAB calculated temperature distribution plot for a thin-film semiconductor laser having a length of 1000 μm, a width of 200 μm, a 3 μm thick p-layer, a 300 nm p-n junction, a 3 μm thick n-layer a total thermal power of 200 watts, a thermal power density of 100 kw/cm², and with the heat removing architecture shown in FIG. 2;

FIG. 3B is a table showing simulation results for different thicknesses of the n-layer for both single-sided and double-sided heat removing architectures;

FIG. 4 is a plot of the temperature difference between the p-n junction and the heat sink under different thermal powers for the same size thin-film semiconductor lasers with the same boundary conditions;

FIG. 5 is a plot of the temperature difference between the p-n junction and the heat sink under the same thermal power density for different size thin-film semiconductor lasers with the same boundary conditions;

FIG. 6 is a plot of the temperature difference between the p-n junction and the heat sink under different thermal power densities for the same thin-film semiconductor laser under different boundary conditions;

FIG. 7 is a schematic diagram of a thin-film semiconductor laser still attached to the GaAs substrate on which it is grown;

FIGS. 8A-8D are schematic diagrams showing a generalized fabrication procedure for the thin-film semiconductor lasers of the present invention;

FIG. 9 is a schematic diagram of a thin-film semiconductor laser wafer bonded to a supporting substrate;

FIG. 10 is a schematic diagram of thin-film semiconductor lasers 200 surrounded by wax 570 and ready to be released; and

FIGS. 11A-11C are schematic diagrams showing a cleaving mirror fabrication technique.

### DETAILED DESCRIPTION OF PREFERRED EMBODIMENTS

A traditional high power semiconductor laser, also called a laser diode (LD), with near 100 μm thick chip thickness is usually designed so that heat is removed or dissipated predominantly from only one side of the laser structure. When the generated heat from a laser diode (LD) PN junction starts to accumulate, the temperature difference between the junction and the chip-heat-sink interface will increase. The thermal stress due to the different thermal expansion coefficients of the LD, the solder, and the sub-mount materials will also increase. This will degrade the laser performance in the short term and will reduce laser lifetimes in the long term.

To overcome this problem, the present invention provides a thin-film semiconductor laser device that utilizes a double-sided heat removal technique and architecture. The term “thin-film semiconductor laser”, as used herein, refers to a semiconductor laser having a p-i-n structure, in which the thickness of the p-layer is no more than 10 times the thickness of the n-layer, or the thickness of the n-layer is no more than 10 times the thickness of the p-layer.

The thin-film semiconductor laser device of the present invention exhibits a p-n junction temperature that is only a few degrees higher than the sub-mount temperature. This greatly reduces the thermally related losses and thermally generated stresses of the chip.

Simulations have shown that if the thickness is decreased from 100 μm to 50 μm, the temperature difference drops by nearly 40%, e.g., from 50° C. to about 30° C.

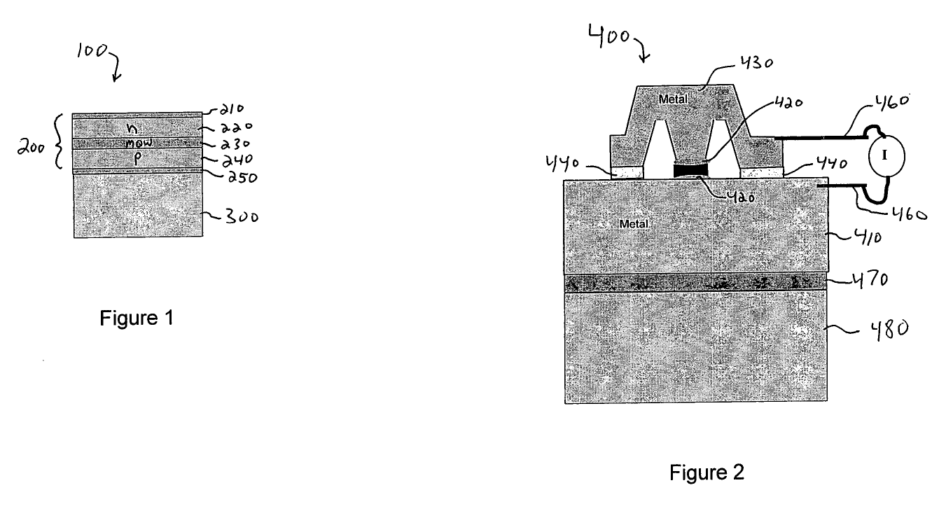

FIG. 1 is a schematic diagram of one preferred thin film semiconductor laser structure 100 used in the thin film semiconductor laser device of the present invention. For ease of illustration, the relative sizes of the individual components of the thin film semiconductor laser structure 100 are not accurately depicted in FIG. 1.

The thin-film semiconductor laser structure 100 includes a thin-film semiconductor laser 200 supported by a thermally conductive supporting layer 300. The thin-film semiconductor laser 200 suitably includes a first GaAs layer 210, an n-InGaP layer 220, a p-n junction MQW layer 230, a p-InGaP layer 240 and a second GaAs layer 250. This is an Alumina free GaAs/InGaP/InGaAsP/AlAs material system that is typically used for 808 nm or other short wavelength IR pump lasers. However, any other semiconductor material system may be used for the thin-film semiconductor laser 200. The thin-film semiconductor laser 200 is preferably mounted on the thermally conductive supporting layer 300 such that the p-layer 240 is closest to the thermally conductive supporting layer 300. This configuration will also be referred to herein as a “P-side down” configuration.

The thermally conductive supporting layer 300 is suitably Al or Cu, and is preferably no thicker than approximately 25 μm. This is much thinner than the substrate on which the thin-film semiconductor laser 200 is grown, which is typically at least 100 μm thick. Other thermally conductive materials, such as SiC or diamond can also be used as the thermally conductive supporting layer 300.

The total thickness of the thin-film semiconductor laser 200 is preferably approximately 6 μm, with an approximately 3 μm thick p-layer 250, an approximately 3 μm thick n-layer 220 and an approximately 300 nm thick p-n junction core layer 230 in between. However, the total thickness of the thin-film semiconductor laser 200 can be greater than or less than 6 μm, as long as the thickness of the p-layer 240 is no more than 10 times the thickness of the n-layer 220, or the thickness of the n-layer 220 is no more than 10 times the thickness of the p-layer 240.

In the embodiment of FIG. 1, the temperature between the p-n junction 230 and the heat sink (not shown) can be reduced down to 3° C. difference at a given generated thermal power of 2 watts using a double-sided heat removing structure, as will be explained in more detail below.

FIG. 2 is a schematic diagram showing one preferred embodiment of the thin film semiconductor laser device 400 of the present invention, which utilizes the thin-film semiconductor laser structure 100 of FIG. 1. For ease of illustration, the relative sizes of the individual components of the thin film semiconductor laser device 400 are not accurately depicted in FIG. 2.

The thermally conductive supporting layer 300 of the thin-film semiconductor laser structure 100 is bonded to thermally conductive sub-mount 410, preferably a metal mount, with bonding material 420, preferably solder. A thermally conductive structure 430, preferably a metal structure, is bonded to the top of the thin-film semiconductor laser structure 100 with bonding material 420, preferably solder. The thermally conductive structure 430 is attached to the thermally conductive sub-mount 410 with a thermally conductive and electrically insulating material 440, suitably diamond. In the embodiment shown in FIG. 2, the thermally conductive structure 430 is “M”-shaped, and makes thermal contact with the thermally conductive sub-mount 410 at two places. However, any shape or configuration can be used for the thermally conductive structure 430, and it can make thermal contact with the thermally conductive sub-mount 410 at only one place or more than two places while still falling within the scope of the present invention. A current source 450 is connected to the thermally conductive structure 430 and the thermally conductive sub-mount 410 via electrical leads 460, and provides a driving current to the thin-film semiconductor laser 200.

The thermally conductive sub-mount 410 of the thin-film semiconductor laser device 400 is typically mounted on a thermoelectric cooler 470, which in turn is mounted to a heat sink 480.

### Analysis of Thermal Design

Most semiconductor lasers can be simplified as a p-i-n structure when considering the thermal design. Since the carrier concentrations in both the p-layer 240 and the n-layer 220 are much higher than that in the p-n junction region 230, an applied voltage will mostly drop to the intrinsic region due to its high electrical resistance. In fact, majority of the electron-hole pairs are recombined around this region radiatively or non-radiatively. The non-radiative recombination will generate heat and further increase the non-radiative recombination rate.

Many factors including thermal conductivity, coefficient of thermal expansion, and other material properties need to be carefully considered in the thermal design. Thermal resistance determines the efficiency of heat transfer as shown in equation (1):

$${R}_{th} = \frac{L}{K \times A} , \qquad ( 1 )$$

where K is the thermal conductivity, L is the length, A is the cross-sectional area. To minimize the thermal resistance, a material with good thermal conductivity should be chosen and the distance between the heat source (e.g. the p-n junction 230) and the heat sink 480 should be decreased as much as possible.

The thermal stress is determined by the thermal expansion coefficient difference and the temperature difference as shown in equation (2):

$$σ = ( \frac{E}{1 - ν} ) \times ( {α}_{T 1} - {α}_{T 2} ) \times Δ T , \qquad ( 2 )$$

where E is Young's Modulus, is Poisson Ratio, αT1, and αT2 are the coefficients of thermal expansion for each material, respectively, ΔT is the temperature difference. To minimize the thermal stress, matched materials should be chosen and the temperature difference should be controlled.

If the temperature of the p-n junction 230 can be significantly reduced, the laser performance will be greatly improved. To achieve that, the thin-film semiconductor laser structure 100 is made thinner to allow the heat sink 480 to get closer to the primary heat source, which is the p-n junction 230. Furthermore, a thermally conductive sub-mount 410 with good thermal conductivity should be used so that the heat removing speed can be increased.

### Simulation of Thermal Design

Simulations were performed based on a broad-area thin-film semiconductor laser 200 with a 3 μm thick p-layer 240, a 300 nm p-n junction 230 and a 3 μm thick n-layer 220. Other parameters, including the length and the width of the thin-film semiconductor laser 200, the thermal power generated from the p-n junction 230 and the boundary conditions were adjusted to study the heat transfer and temperature distribution.

The finite element analysis software “Femlab Version 2.3” (FEMLAB) was used to perform the simulations. All the simulations are based on the following two equations:
−∇·(K·∇T)=Q+htrans·(Text−T)+Ctrans·(Tamb⁴−T⁴) (3)
n·(K·∇T)=q+h·(Tₑₓₜ−T)+Const·(T_{amb}⁴−T⁴) (4)
where K is the thermal conductivity, Q is the heat source, htrans is the convection heat transfer coefficient, Text is the external temperature, Ctrans is the user-defined constant, Tamb is the ambient temperature, n is the normal vector, q is heat flux, h is the heat transfer coefficient, Const is problem-dependent constant.

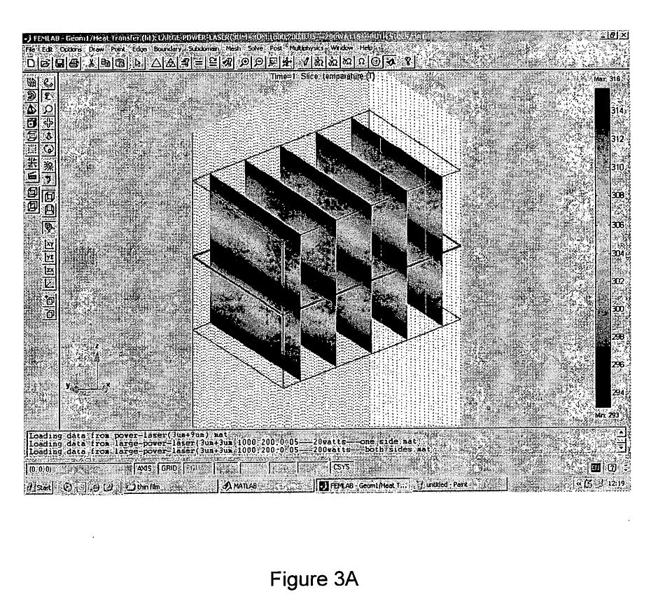

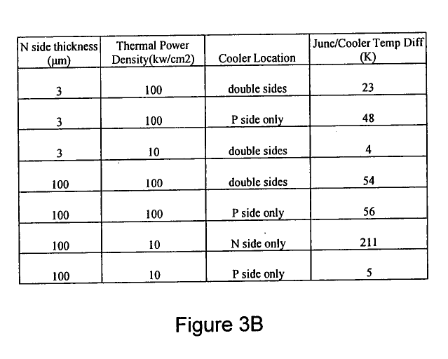

First the temperature differences between the p-n junction 230 and the heat sink 480 under different thermal powers were measured. The same laser size and boundary conditions were used for comparison. FIG. 3A shows a FEMLAB calculated temperature distribution plot for a thin-film semiconductor laser 200 having a length of 1000 μm, a width of 200 μm, a 3 μm thick p-layer 240, a 300 nm p-n junction 230, a 3 μm thick n-layer 220 a total thermal power of 200 watts, a thermal power density of 100 kw/cm², and with the heat removing architecture shown in FIG. 2. The calculated temperature difference between the p-n junction 230 and the thermally conductive sub-mount 410 was 23° K. The temperature distribution plot is a useful tool for determining how fast the heat can be dissipated through a single or double sided sub-mount packaging.

FIG. 3B is a table showing simulation results for different thicknesses of the n-layer 220. The “Cooler Location” refers to the heat removal architecture. “Double-sides” refers to the architecture shown in FIG. 2, in which one side of the thin-film semiconductor laser structure 100 is mounted on the thermally conductive sub-mount 410 and the other side of the thin-film semiconductor laser structure 100 is in thermal contact with a thermally conductive structure 430. “P-side only” refers to an architecture in which the thin-film semiconductor laser structure 100 is mounted on the thermally conductive sub-mount 410 p-side down and a thermally conductive structure 430 is not used on the other side of the thin-film semiconductor laser structure 100. “N-side only” refers to an architecture in which the thin-film semiconductor laser structure 100 is mounted on the thermally conductive sub-mount 410 n-side down and a thermally conductive structure 430 is not used on the other side of the thin-film semiconductor laser structure 100.

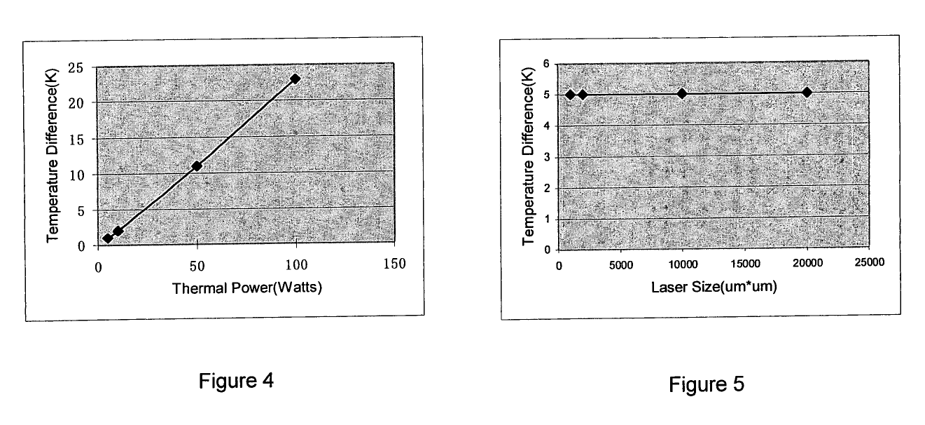

Second, simulations were performed with different size lasers under the same thermal power density with the same boundary conditions. FIG. 4 summarizes several calculated results. It is a plot of the temperature difference between the p-n junction 230 and the heat sink 480 under different thermal powers for the same size thin-film semiconductor lasers 200 with the same boundary conditions. As shown in FIG. 4, if the thermal power is increased, the temperature between the p-n junction 230 and the heat sink 480 will also increase.

FIG. 5 is a plot of the temperature difference between the p-n junction 230 and the heat sink 480 under the same thermal power density for different size thin-film semiconductor lasers 200 with the same boundary conditions. The plot shows that under the same thermal power density, the temperature difference between the p-n junction 230 and the heat sink 480 is the same. This result means that the thermal power density, not the thermal power, is the factor that determines the temperature difference between the p-n junction 230 and the heat sink 480.

This simulation is based on a broad-area thin-film semiconductor laser 200. For buried hetero-structure lasers, the thermal power density will be larger, so the actual temperature difference between the p-n junction 230 and the heat sink 480 will be higher.

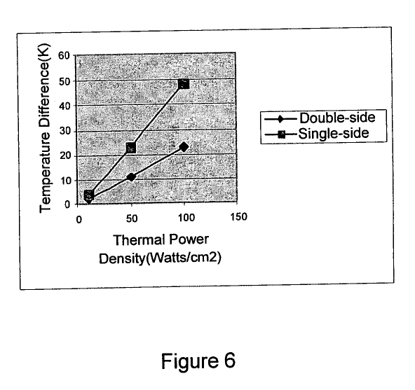

FIG. 6 is a plot of the temperature difference between the p-n junction 230 and the heat sink 480 under different thermal power densities for the same thin-film semiconductor laser 200 under different boundary conditions. The plot of FIG. 6 shows that a double-sided heat removing architecture, such as the one shown in FIG. 2, greatly improves heat dissipation, and the temperature difference between the p-n junction 230 and the heat sink 480 drops about 50% compared with one-sided heat removing architecture.

### Thin-Film Semiconductor Laser Processing Techniques

### General Methodology

The ability to remove heat from both sides of the thin-film semiconductor laser 200 results in the reduction of many different kinds of losses and allows for high output powers. However, mass production or “on wafer processing” techniques are needed to fabricate and process thin-film semiconductor lasers 200 and separate them into individual laser bars in batch. Handling large area 100 μm thick laser wafers is now common. However, a bottom supporting material is needed to handle the thin-film semiconductor laser 200.

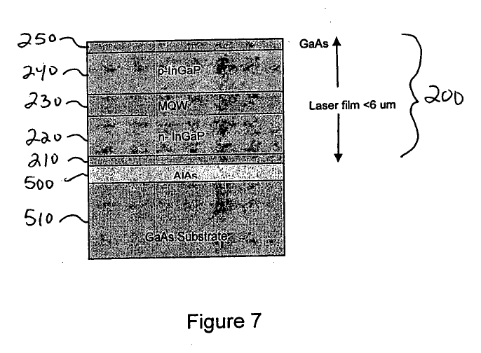

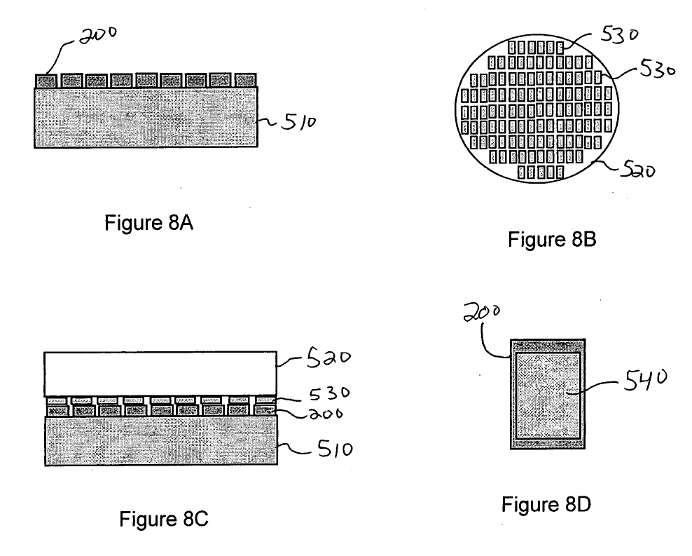

FIG. 7 shows the thin-film semiconductor laser 200 still attached to the GaAs substrate 510 on which it is grown. An AlAs sacrificial layer 500 is used to remove the thin-film semiconductor laser 200 from the GaAs substrate 510. FIGS. 8A-8D are schematic diagrams illustrating one procedure for fabricating the thin-film semiconductor lasers 200.

The fabrication process starts with the grown wafer shown in FIG. 7. Metallization is done first, and the metal is used as the mask to dry etch through the n-InGaP layer 220. A minor wet etch is then done to stop at the GaAs layer 210. This will separate each individual thin-film semiconductor laser 200, as shown in FIG. 8A. The thin GaAs layer 210 is used to prevent metal from getting into the trenches when we bottom metallization is done. The laser mirrors are also etched in this case.

A transparent substrate 520 is then used to prepare structures 530 having a layer of inter-medium material, with a supporting metal material and an evaporated solder material placed on top of it, as shown in FIG. 8B.

After appropriate alignment under a microscope, the solder is annealed and the two substrates 520 and 510 are bonded, with each individual thin-film semiconductor laser 200 bonded as shown in FIGS. 8C and 8D. The metal pattern 540 is a little bit smaller than the pattern of the thin-film semiconductor lasers 200 to avoid unnecessary facet cover by the solder. After the bonding, the semiconductor substrate 510 is etched away, and the bottom contact layer (GaAs layer 250) is metallized. The metallization put on the GaAs layer 250 will become the thermally conductive supporting layer 300 shown in FIG. 1. The thermally conductive supporting layer 300 should have better thermal conductivity than that of the semiconductor substrate 510. The thermally conductive supporting layer 300 should also have a good material interface with the thin-film semiconductor laser 200 without causing thermal and mechanical stress.

The individual thin-film semiconductor lasers 200 are then released from the transparent substrate 520. The thin GaAs contact layer 250 and metal layer (element 300 in FIG. 1) will easily be broken away to obtain each well-defined thin-film semiconductor laser 200.

### Etched Mirror Approach

In this approach, a very thin (preferably 1-2 mils thick) Al or Cu film is used as the material for the thermally conductive supporting layer 300 to replace the semiconductor substrate 510. Each thin-film semiconductor laser 200 is separated using dry or wet chemical etching. The supporting metal layer is also etched through before releasing each thin-film semiconductor laser 200 using chemical solvents, which dissolve away the bottom holding wax materials.

Al foil is inexpensive and readily available. The thickness of a typical thin Al foil is around 20-25 μm. There may have thicker or thinner foils, but the more important feature is that they are mechanically sound to support the thin-film semiconductor laser 200, and that it does not take a long time to etch through.

The surface roughness of a typical super market grade Al foil was tested and it was mounted to a glass plate with wax. The surface roughness has about 400-800 nm deep variations. These height variations can be easily covered up with Indium reflow under high temperature (about 200 degree C.). The foil is first cleaned with solvents and then the thin Al₂O₃ layer on the Al foil is removed with HCl or NaOH.

After depositing p-metal on the p-side of the thin-film semiconductor laser 200, a thin AuSn layer is evaporated on the surface. The cleaned Al foil is then mounted on top of the GaAs layer 250 under AuSn melting temperature. After this step, two different processing approaches can be used to separate individual thin-film semiconductor lasers 200.

1. Separation Before Substrate Removal

With this approach, lithography is used to etch through the Al foil, AuSn layer, and the thin-film semiconductor laser layer. The etching stops at the etch-stop layer 500 to separate each individual thin-film semiconductor laser 200 right after the Al foil bonding process. Since the Al material is chemically active with any kind of acids or bases, the undercutting etching needs to be carefully controlled during the etching processes.

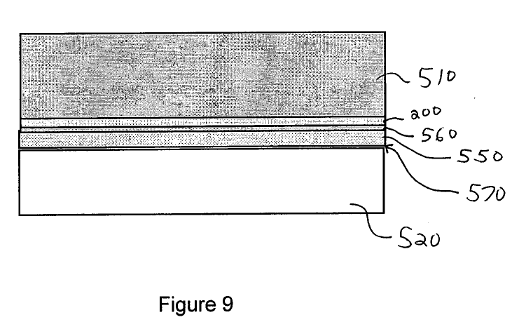

As shown in FIG. 9, after etching through the Al foil, the AuSn layer 560, and the thin-film semiconductor laser layers 200, the wafer is to a quartz supporting substrate 520 with wax 570 so that the wafer can be thinned down. The wax 570 will fill all the etched trenches and touch the etched facets.

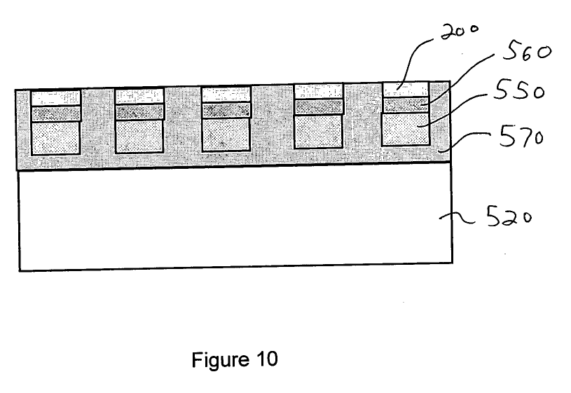

After the wax bonding, the wafer is thinned down and the GaAs substrate 510 is etched away, as well as the etch stop layer 500. FIG. 10 shows the thin-film semiconductor lasers 200 surrounded by wax 570 and ready to be released. The individual thin-film semiconductor lasers 200 are then released in a solvent environment and picked up for double-sided heat removal packaging. The Al foil 550 is the thermally conductive supporting layer 300 shown in FIG. 1.

2. Separation Before Substrate Removal

With this approach, the wafer is wax bonded to the quartz substrate 520 right after the Al foil 550 is bonded. The GaAs substrate 510 is then thinned down and etched away, and the etch stop layer 500 is also etched away. This time the n-layer 220 of thin-film semiconductor lasers 200 is exposed for the next step processing.

Lithography is then performed to etch. through the thin-film semiconductor laser layer, the AuSn layer 560, and the Al foil 550 to separate each individual thin-film semiconductor laser 200. After this is done, the remaining wafer/quartz substrate combination is placed in a solvent environment to release all the thin-film semiconductor lasers 200. One needs to watch over any potential under-cutting etchings of the Al foil 550. If the undercutting is very serious, Cu foil instead of Al foil can be used as the thermally conductive supporting layer 300. However, the etching rate of the Cu foil is slower and the availability of Cu foil is not as good as Al foil.

### Cleaving Mirror Approach

The etched mirror approach described above is a reasonably simple and good method to replace the low thermal conductivity semiconductor substrate 510 with a thermally conductive supporting layer 300. However, as described above, the etched facets will be exposed to wax, solvent, and air and this may produce imperfect facet passivation, which can cause reliability problems.

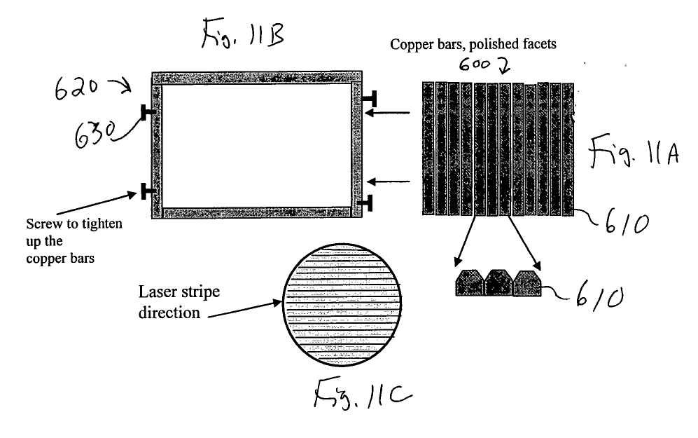

An alternative approach is to accomplish cleave facets by using a copper bar fixtures, such as the copper bar fixture 600 shown in FIG. 11A. The widths of the individual copper bars 610 that make up the copper bar fixture 600 are the same width as the desired length of the thin-film semiconductor lasers 200. The copper bars 610 are tightly controlled with nearly equal height and with very flat surface.

The copper bars 610 are placed in a fixture 620, shown in FIG. 11B for aligning them to the same height by putting the polished surface against a flat surface and locking the fixture using locking screws 630. After evaporating In or AuSn onto the polished bonding surface, the copper bars 610 are ready for wafer bonding.

After putting down the p-layer metal, the thin-film semiconductor laser wafer is bonded p-side down to the flat copper bar surface with the laser stripe direction perpendicular to the long side of the copper bars 610, as illustrated in FIG. 11C. After annealing the wafer at the In or AuSn melting temperature, the wafer can be bonded to the copper bar fixture 600. The semiconductor substrate 510 is then thinned downed and the semiconductor substrate 510 and the etch-stop layer 500 are chemically etched to stop at the n-side contact layer 210.

After completing the n-side metallization, the thin-film semiconductor laser wafer is ready for cleaving. Since the thin-film semiconductor laser wafer is really thin, when the copper bars 610 are separated one-by-one, they will automatically cleave at the bar separation point. The thin-film semiconductor laser 200 with a copper bar 610 bonded on one side (which is now the thermally conductive supporting layer 300) can be easily bonded onto another copper bar, which will become the thermally conductive structure 430 thus completing the double-sided heat removing architecture.

The foregoing embodiments and advantages are merely exemplary, and are not to be construed as limiting the present invention. The present teaching can be readily applied to other types of apparatuses. The description of the present invention is intended to be illustrative, and not to limit the scope of the claims. Many alternatives, modifications, and variations will be apparent to those skilled in the art. Various changes may be made without departing from the spirit and scope of the present invention, as defined in the following claims.

What is claimed is:

1. A semiconductor laser device, comprising:
a thin-film semiconductor laser;
a thermally conductive supporting layer attached to a first side of the thin-film semiconductor laser; and
a thermally conductive structure in thermal communication with a second side of the thin-film semiconductor laser.

2. The semiconductor laser device of claim 1, wherein the thermally conductive supporting layer is attached to a p-side of the thin-film semiconductor laser.

3. The semiconductor laser device of claim 1, wherein the thermally conductive supporting layer comprises Al foil.

4. The semiconductor laser device of claim 3, wherein the Al foil has a thickness of 20 μm to 25 μm.

5. The semiconductor laser device of claim 1, wherein the thermally conductive supporting layer comprises Cu foil.

6. The semiconductor laser device of claim 5, wherein the Cu foil has a thickness of 20 μm to 25 μm.

7. The semiconductor laser device of claim 1, wherein the thermally conductive structure comprises a metal.

8. The semiconductor laser device of claim 1, wherein the thin-film semiconductor laser comprises:
an approximately 3 μm p-layer;
an approximately 3 μm n-layer; and
a p-n junction between the p-layer and the n-layer.

9. The semiconductor laser device of claim 8, wherein the p-n junction layer is approximately 300 nm thck.

10. A semiconductor laser device, comprising:
a thin-film semiconductor laser;
a thermally conductive supporting layer attached to a first side of the thin-film semiconductor laser;
a thermally conductive sub-mount attached to the thermally conductive layer; and
a thermally conductive structure in thermal communication with a second side of the thin-film semiconductor laser and the thermally conductive supporting layer.

11. The semiconductor laser device of claim 10, wherein the thermally conductive supporting layer is attached to a p-side of the thin-film semiconductor laser.

12. The semiconductor laser device of claim 10, wherein the thermally conductive supporting layer comprises Al foil.

13. The semiconductor laser device of claim 12, wherein the Al foil has a thickness of 20 μm to 25 μm.

14. The semiconductor laser device of claim 10, wherein the thermally conductive supporting layer comprises Cu foil.

15. The semiconductor laser device of claim 14, wherein the Cu foil has a thickness of 20 μm to 25 μm.

16. The semiconductor laser device of claim 10, wherein the thermally conductive structure comprises a metal.

17. The semiconductor laser device of claim 10, wherein the thin-film semiconductor laser comprises:
an approximately 3 μm p-layer;
an approximately 3 μm n-layer; and
a p-n junction between the p-layer and the n-layer.

18. The semiconductor laser device of claim 17, wherein the p-n junction layer is approximately 300 nm thick.

19. The semiconductor laser device of claim 10, wherein the thermally conductive structure thermally contacts the thermally conductive sub-mount at two places.

20. The semiconductor laser device of claim 10, wherein the thermally conductive structure is in thermal communication with a heat sink.

21. The semiconductor laser device of claim 20, further comprising a thermoelectric cooler positioned between the thermally conductive structure and the heat sink.
